(19) United States
(12) Patent Application Publication
(10) Pub. No.: US 2026/0144047 A1
(43) Pub. Date: May 21, 2026

(54) INTERCONNECT STRUCTURE INCLUDING RE-SHAPED CONDUCTIVE INTERCONNECT AND METHOD FOR MANUFACTURING THE SAME

(71) Applicant: TAIWAN SEMICONDUCTOR MANUFACTURING COMPANY, LTD., Hsinchu (TW)

(72) Inventors: Chia-Wei SU, Hsinchu (TW); Li-Ling SU, Hsinchu (TW); Yung-Hsu WU, Hsinchu (TW); Hsin-Ping CHEN, Hsinchu (TW); Chih Wei LU, Hsinchu (TW); Cheng-Hsiung TSAI, Hsinchu (TW); Chieh-Han WU, Hsinchu (TW); Wei-Hao LIAO, Hsinchu (TW)

(73) Assignee: TAIWAN SEMICONDUCTOR MANUFACTURING COMPANY, LTD., Hsinchu (TW)

(21) Appl. No.: 18/952,776

(22) Filed: Nov. 19, 2024

(51) Int. Cl. H01L 23/528; H01L 21/02; H01L 21/768

(52) U.S. Cl. CPC H10W 20/435; H10P 14/6548; H10P 14/683; H10W 20/089

(57) ABSTRACT

A method for manufacturing a semiconductor device includes: forming a first conductive interconnect which penetrates a dielectric layer disposed over a substrate; forming a patterned dielectric layer on the dielectric layer, the patterned dielectric layer being formed with a trench and the first conductive interconnect being exposed from the trench; selectively forming a blocking layer to cover the first conductive interconnect, the blocking layer being formed using an acidic solution including a blocking material; selectively forming a barrier material layer on the dielectric layer and the patterned dielectric layer; removing the blocking layer; forming a conductive material layer on the barrier material layer; and removing a portion of the conductive material layer and a portion of the barrier material layer to form a second conductive connected to the first conductive interconnect.

### BACKGROUND

The semiconductor integrated circuit (IC) industry has experienced tremendous advancements over the past decades and is still experiencing vigorous development. With the dramatic advances in IC design, new generations of ICs have small and complex circuits and semiconductor features. A damascene process (for example, a single damascene process or a dual damascene process) is one of the techniques used for forming back-end-of-line (BEOL) or middle-end-of-line (MEOL) interconnect structures. The interconnect structures play an important role in miniaturization and electrical performance of the new generations of ICs. Thus, the industry pays much attention to the development of the interconnect structures.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor device in accordance with some embodiments.

FIGS. 2 to 13 are schematic views illustrating some stages of the method as depicted in FIG. 1 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “upper,” “lower,” “top,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be noted that the element(s) or feature(s) are exaggeratedly shown in the figures for the purposed of convenient illustration and are not in scale.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The term “source/drain region(s)” may refer to a source or a drain, individually or collectively dependent upon the context.

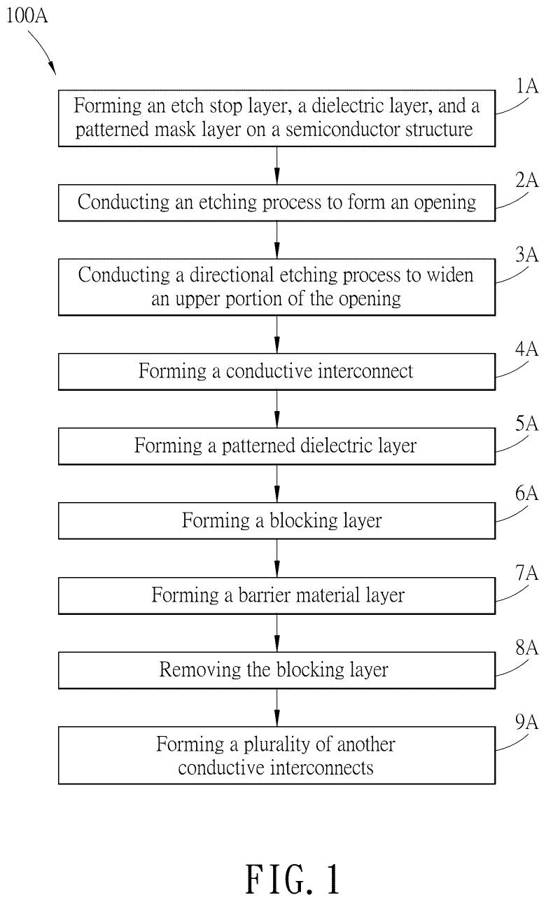

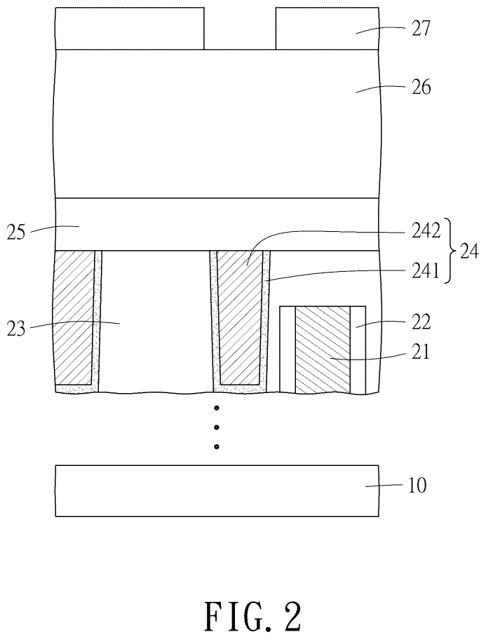

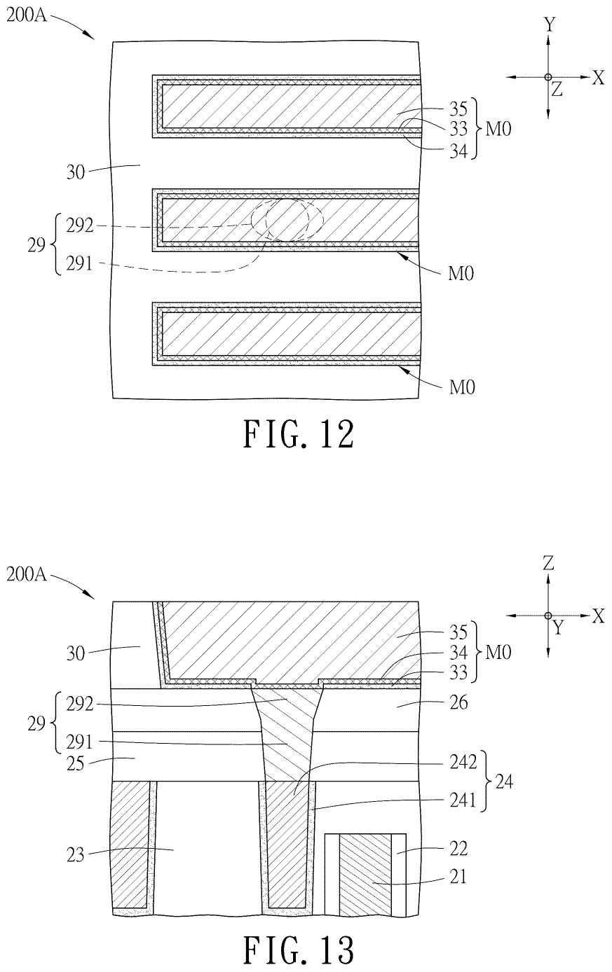

The present disclosure is directed to a semiconductor device including an interconnect structure in which a conductive interconnect (for example, but not limited to, a via contact) disposed on and connected to a conductive feature (for example, a conductive contact disposed on and connected to a gate structure or a source/drain region of a transistor) is reshaped, so as to reduce interface resistance and bulk resistance of the conductive interconnect and to enhance performance of the interconnect structure. In addition, a barrier layer of another conductive interconnect disposed on the conductive interconnect is not formed on the conductive interconnect. FIG. 1 is a flow diagram illustrating a method 100A for manufacturing a semiconductor device (for example, a semiconductor device 200A shown in FIGS. 12 and 13) in accordance with some embodiments. FIGS. 2 to 11 illustrate schematic views of some intermediate stages of the method 100A. Some portions may be omitted in FIGS. 2 to 13 for the sake of brevity. Additional steps can be provided before, after or during the method 100A, and some of the steps described herein may be replaced by other steps or be eliminated.

Referring to FIG. 1 and the example illustrated in FIG. 2, the method 100A begins at step 1A, where an etch stop layer 25, a dielectric layer 26, and a patterned mask layer 27 are formed on a semiconductor structure disposed over a substrate 10 in a Z direction normal to the substrate 10. The substrate 10 is only shown in FIG. 2.

In some embodiments, the substrate 10 is a semiconductor substrate, which may include, for example, but not limited to, an elemental semiconductor or a compound semiconductor. The elemental semiconductor includes a single species of atoms, such as silicon or germanium in column XIV of a periodic table, and may be in a crystal form, a polycrystalline form, or an amorphous form. Other suitable elemental semiconductor materials are within the contemplated scope of the present disclosure. The compound semiconductor includes two or more elements, and examples thereof may include, but not limited to, silicon carbide, gallium arsenide, gallium phosphide, indium phosphide, indium arsenide, indium antimonide, silicon germanium, gallium arsenide phosphide, aluminum indium arsenide, aluminum gallium arsenide, gallium indium arsenide, gallium indium phosphide, and gallium indium arsenide phosphide. Other suitable compound semiconductor materials are within the contemplated scope of the present disclosure. The compound semiconductor may have a gradient feature in which the compositional ratio thereof changes from one location to another location therein. The compound semiconductor may be formed over a silicon substrate. The compound semiconductor may be strained. In some embodiments, the semiconductor substrate may include a multilayer compound semiconductor substrate. In some embodiments, the semiconductor substrate may be a semiconductor on insulator (SOI) (e.g., silicon germanium on insulator (SGOI)). Generally, an SOI substrate includes a layer of a semiconductor material such as epitaxial silicon, germanium, or silicon germanium. Other suitable materials are within the contemplated scope of the present disclosure. The SOI substrate may be doped with a P-type dopant, for example, but not limited to, boron, aluminum, or gallium. Other suitable P-type dopant materials are within the contemplated scope of the present disclosure. Alternatively, the SOI substrate may be doped with an N-type dopant, for example, but not limited to, nitrogen, phosphorus, or arsenic. Other suitable N-type dopant materials are within the contemplated scope of the present disclosure.

In some embodiments, the semiconductor structure includes a semiconductor feature (not shown, for example, but not limited to, a transistor) disposed on the substrate 10. The transistor includes a gate dielectric (not shown) disposed on the substrate 10, a gate electrode 21 disposed on the gate dielectric, and a pair or source/drain regions (not shown) disposed at two opposite sides of the gate electrode 21. The semiconductor structure further includes a pair of sidewall spacers 22 laterally covering the gate electrode 21 and the gate dielectric, a dielectric layer 23 disposed on the substrate 10 to cover the transistor and the sidewall spacers 22, and a metal contact 24 penetrating the dielectric layer 23 and connected to the gate electrode 21 or a corresponding one of the pair of the source/drain regions. As shown in FIG. 2, the metal contact 24 is connected to a corresponding one of the source/drain regions.

In some embodiments, the gate dielectric may include, for example, but not limited to, silicon oxide, silicon nitride, silicon oxynitride, a suitable high-k material (for example, but not limited to, hafnium oxide, zirconium oxide, zirconium aluminum oxide, hafnium aluminum oxide, hafnium silicon oxide, or aluminum oxide), or combinations thereof. Other suitable materials for the gate dielectric are within the contemplated scope of the present disclosure.

In some embodiment, the gate electrode 21 may include, for example, but not limited to, aluminum, copper, tungsten, cobalt, ruthenium, titanium, tantalum, molybdenum, nickel, platinum, titanium nitride, tantalum nitride, or combinations thereof. Other suitable materials for the gate electrode 21 are within the contemplated scope of the present disclosure.

In some embodiments, the source/drain regions are formed by an epitaxial growth process, for example, but not limited to, a selective epitaxial growth (SEG) process. Other suitable processes for forming the source/drain regions are within the contemplated scope of the present disclosure. In addition, the source/drain regions may be doped with germanium, boron, phosphorus, or arsenic. For example, in some embodiments, one or more epitaxial layers are grown by the epitaxial growth process with, for example, phosphorus doping when the source/drain regions to be formed are n-FET source/drain regions. In some embodiments, one or more epitaxial layers are grown by the epitaxial growth process with, for example, geranium doping when the source/drain regions to be formed are p-FET source/drain regions.

In some embodiments, the sidewall spacers 22 may be formed by conducting a suitable deposition process (for example, but not limited to, chemical vapor deposition (CVD) or atomic layer deposition (ALD)) to conformally form a spacer layer on the substrate 10 to cover the gate electrode 21 and the gate dielectric, followed by conducting an anisotropic etching process (for example, but not limited to, an anisotropic dry etching process) to remove horizontal portions of the spacer layer. Other suitable processes for forming the sidewall spacers 22 are within the contemplated scope of the present disclosure. In some embodiments, the sidewall spacers 22 (or the spacer layer) may include, for example, but not limited to, silicon oxide, silicon nitride, silicon oxynitride, silicon carbon nitride, silicon oxycarbonitride, or low-dielectric constant (k) materials. Other suitable materials for forming the sidewall spacer 22 (or the spacer layer) are within the contemplated scope of the present disclosure.

In some embodiments, the dielectric layer 23 may include, for example, but not limited to, silicon oxide, silicon nitride, silicon carbide, silicon oxycarbide, silicon oxynitride, silicon carbonitride, silicon oxycarbonitride, other low-k dielectric materials, or combinations thereof. Other suitable materials for forming the dielectric layer 23 are within the contemplated scope of the present disclosure. In some embodiments, the dielectric layer 23 may be formed by a suitable deposition process, for example, but not limited to, CVD or ALD. Other suitable processes for forming the dielectric layer 23 are within the contemplated scope of the present disclosure.

The metal contact 24 includes a barrier layer 241 and a conductive bulk region 242, which is covered by the barrier layer 241 at a side surface and a bottom surface thereof. In some embodiments, the barrier layer 241 may include, for example, but not limited to, tantalum, cobalt, ruthenium, tantalum nitride, or combinations thereof. Other suitable materials for the barrier layer 241 are within the contemplated scope of the present disclosure. In some embodiments, the conductive bulk region 242 may include ruthenium, tungsten, cobalt, molybdenum, copper, or combinations thereof. Other suitable materials for the conductive bulk region 242 are within the contemplated scope of the present disclosure.

The etch stop layer 25 is formed on the dielectric layer 23 to cover the metal contact 24. The etch stop layer 25 has good conformity and isolation capability. In some embodiments, the etch stop layer 25 may include, for example, but not limited to, silicon nitride, silicon nitride doped with carbon, silicon oxide, silicon oxynitride, silicon oxynitride doped with carbon, silicon carbide, silicon oxycarbide, metal nitride (for example, but not limited to, titanium nitride or aluminum nitride), metal oxide (for example, but not limited to, aluminum oxide), metal carbide (for example, but not limited to, tungsten carbide), or combinations thereof. Other suitable materials for forming the etch stop layer 25 are within the contemplated scope of the present disclosure. The etch stop layer 25 may be configured as a single-layer structure, a bi-layered structure, or a multi-layered structure. In some embodiments, the etch stop layer 25 may be formed by a suitable deposition process, for example, but not limited to, physical vapor deposition (PVD), CVD, ALD, plasma enhanced ALD (PEALD), or plasma enhanced CVD (PECVD). Other suitable deposition techniques are within the contemplated scope of the present disclosure.

The dielectric layer 26 is formed on the etch stop layer 25 opposite to the semiconductor structure. The material and the process for forming the dielectric layer 26 may be the same as or similar to those for forming the dielectric layer 23 described above, and details thereof are omitted for the sake of brevity.

The patterned mask 27 is formed on the dielectric layer 26 opposite to the etch stop layer 25. In some embodiments, the patterned mask 27 may be formed by depositing a mask material layer on the dielectric layer 26 by a suitable deposition process (for example, but not limited to, PVD, CVD, ALD, PEALD, or PECVD), and patterning the mask material layer by a suitable etching process through a patterned photoresist layer (not shown) disposed on the mask material layer. In some embodiments, the patterned photoresist layer may be formed by coating a photoresist layer (not shown) on the mask material layer, soft-baking the photoresist layer, exposing the photoresist layer through a photomask (not shown), post-exposure baking the photoresist layer, and developing the photoresist layer, followed by hard-baking the photoresist layer so as to form the patterned photoresist layer on the mask material layer. The mask material layer is then patterned through the patterned photoresist layer to form the patterned mask 27. In some embodiments, the etching process for patterning the mask material layer includes a dry etching process or a wet etching process. In some embodiments, the patterned photoresist layer may be removed by a suitable removal process (for example, but not limited to, an ashing process or an etch-back process) after the patterned mask 27 is formed. In some embodiments, the patterned photoresist layer may serve as the patterned mask 27.

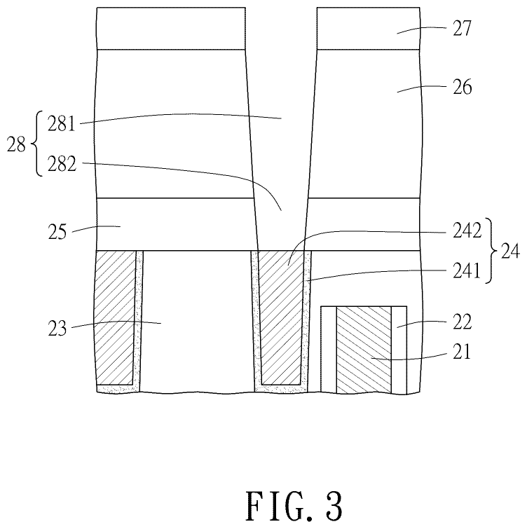

Referring to FIG. 1 and the example illustrated in FIG. 3, the method 100A proceeds to step 2A, where an etching process is conducted to form an opening 28. The opening 28 is formed to penetrate the dielectric layer 26 and the etch stop layer 25, so as to expose the metal contact 24 or the conductive bulk region 242 of the metal contact 24 from the opening 28. In some embodiment, the etching process is an anisotropic etching process, for example, but not limited to, an anisotropic dry etching process. In some embodiments, an etching gas used for the anisotropic dry etching process includes, for example, but not limited to, a chemical reaction-type etching gas, a physical bombardment-type etching gas, or a combination thereof. In some embodiments, the chemical reaction-type etching gas includes, for example, but not limited to, fluoromethane (CH₃F), difluoromethane (CH₂F₂), trifluoromethane (CHF₃), methane (CH₄), tetrafluoromethane (CF₄), octafluorobutene (C₄F₈), hexafluorobutyne (C₄F₆), nitrogen gas (N₂), oxygen gas (O₂), or combinations thereof. In some embodiments, the physical bombardment-type etching gas includes inert gas, for example, but not limited to, helium gas (He), neon gas (Ne), argon gas (Ar), or combinations thereof. In some embodiments, the opening 28 has a circle-like shape in a cross-section of the opening 28 taken in a horizontal plane parallel to the substrate 10. The opening 28 includes an upper opening portion 281 and a lower opening portion 282 disposed below and in spatial communication with the upper opening portion 281. Both of the upper and lower opening portions 281, 282 have the circle-like shape.

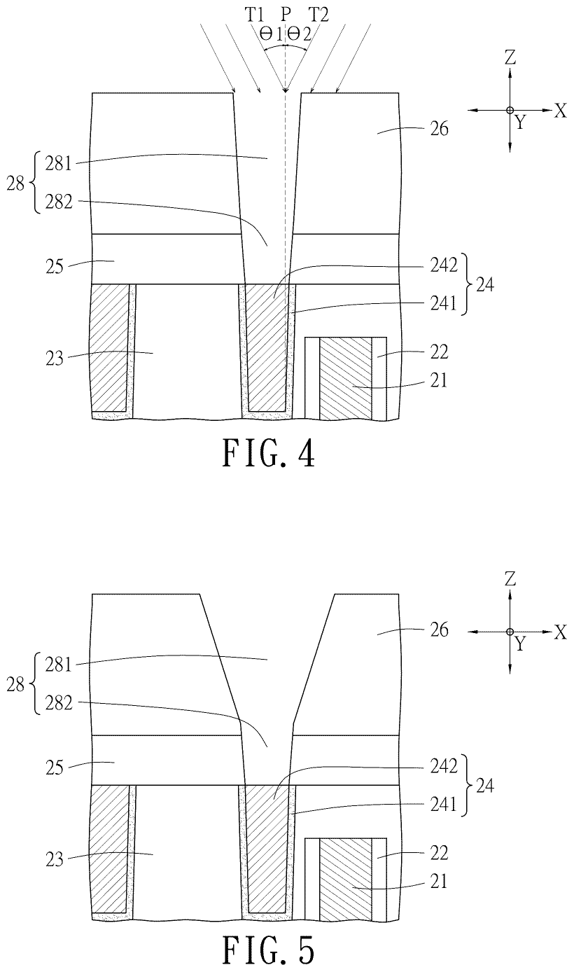

Referring to FIG. 1 and the examples illustrated in FIGS. 4 and 5, the method 100A proceeds to step 3A, where a directional etching process is conducted to widen the upper opening portion 281 of the opening 28. The patterned mask 27 of the structure shown in FIG. 3 is removed by a suitable removal process (for example, but not limited to, an etch-back process) after the opening 28 is formed. Thereafter, the directional etching process is conducted to widen the upper opening portion 281 of the opening 28. The directional etching process (i.e., step 3A) is conducted by sub-steps (i) and (ii) described below.

In sub-step (i), a first directional etching is conducted at a first tilt orientation (T1), which is parallel to a first vertical plane extending in a first direction (for example, a Z direction) normal to the substrate 10 (see FIG. 2) and a second direction (for example, an X direction) transverse to the first direction, and which forms a first tilt angle (Θ₁) relative to a second vertical plane (P) extending in the first direction and a third direction (for example, a Y direction) transverse to the first direction and the second direction. In some embodiments, the first direction (the Z direction), the second direction (the X direction), and the third direction (the Y direction) are perpendicular to one another. In some embodiments, the first and second vertical planes are perpendicular to the horizontal plane and are perpendicular to each other. In some embodiments, the first directional etching is a directional dry etching, and is conducted using an etching gas. In some embodiments, the etching gas includes, for example, but not limited to, a chemical reaction-type etching gas, a physical bombardment-type etching gas, or a combination thereof. In some embodiments, the chemical reaction-type etching gas includes, for example, but not limited to, fluoromethane (CH₃F), difluoromethane (CH₂F₂), trifluoromethane (CHF₃), methane (CH₄), tetrafluoromethane (CF₄), octafluorobutene (C₄F₈), hexafluorobutyne (C₄F₆), nitrogen gas (N₂), oxygen gas (O₂), or combinations thereof. In some embodiments, the physical bombardment-type etching gas includes inert gas, for example, but not limited to, helium gas (He), neon gas (Ne), argon gas (Ar), or combinations thereof.

In sub-step (ii), a second directional etching is conducted at a second tilt orientation (T2), which is parallel to the first vertical plane, and which forms a second tilt angle (Θ₂) relative to the second vertical plane (P). The second tilt orientation (T2) is counter to the first tilt orientation (T1) relative to the second vertical plane (P). The second tilt angle (Θ₂) may be equal to or different from the first tilt angle (Θ₁). In some embodiments, each of the first tilt angle (Θ₁) and the second tilt angle (Θ₂) may be greater than about 0° and up to about 70°. In some embodiments, the second directional etching is a directional dry etching, and is conducted using an etching gas selected from the examples of the etching gas for the first directional etching as described above. After the directional etching process is conducted, a cross-sectional area of the upper opening portion 281 of the opening 28 taken in the horizontal plane parallel to the substrate 10 (see FIG. 2) is increased and a cross-sectional shape of the upper opening portion 281 of the opening 28 taken in the horizontal plane parallel to the substrate 10 is re-shaped from the circle-like shape to an oval-like shape, while a cross-sectional shape of the lower portion 282 of the opening 28 is maintained as the circle-like shape. In some embodiments, after the directional etching process is conducted, a ratio of a push amount of the upper opening portion 281 in the second direction (the X direction) to a push amount of the upper opening portion 281 in the third direction (the Y direction) is greater than about 11, and may be up to about 22. The push amount is defined as an increased amount of a dimension of the upper opening portion 281 in a direction (the second direction or the third direction) after the directional etching process, compared to the dimension before the directional etching process.

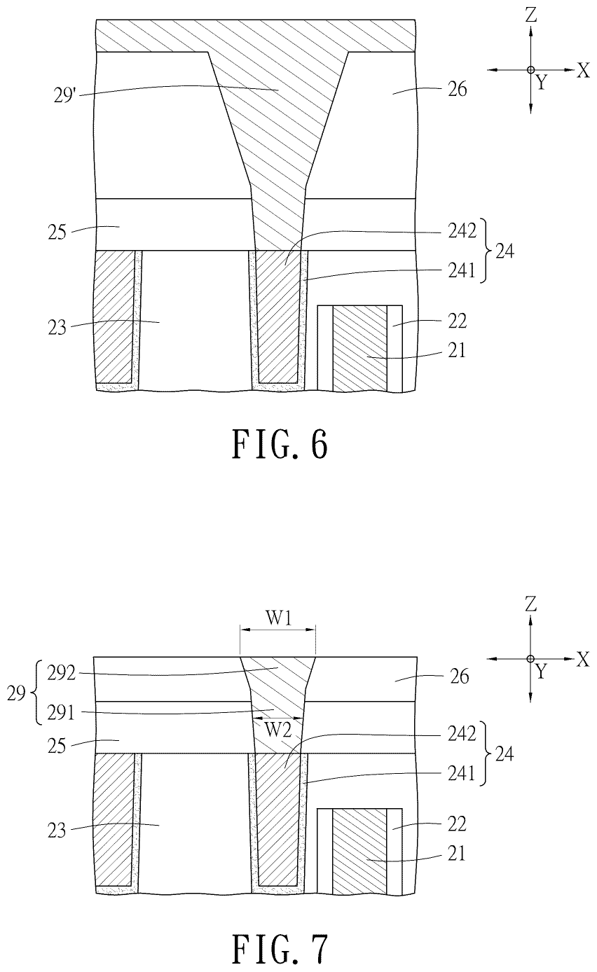

Referring to FIG. 1 and the examples illustrated in FIGS. 6 and 7, the method 100A proceeds to step 4A, where a conductive interconnect 29 is formed. A conductive material layer 29′ (see FIG. 6) for forming the conductive interconnect 29 is formed on the dielectric layer 26 to fill the opening 28 (see FIG. 5). In some embodiments, the conducive material layer 29′ may be formed by a suitable deposition process (for example, but not limited to, electrochemical plating (ECP), electroless deposition (ELD), PVD, CVD, ALD, PEALD, or PECVD) in a bottom-up or gap-filling manner. Other suitable deposition techniques are within the contemplated scope of the present disclosure. A portion of the conducive material layer 29′ and a portion of the dielectric layer 26 are removed by a planarization process (for example, but not limited to, a chemical mechanical planarization (CMP) process) to form the conductive interconnect 29. In some embodiments, the conductive interconnect 29 serves as a via contact, and penetrates the dielectric layer 26 and the etch stop layer 25 such that the conductive interconnect 29 is connected to the metal contact 24 (or the conductive bulk region 242 of the metal contact 24). In some embodiments, the conductive interconnect 29 or the conducive material layer 29′ includes, for example, but not limited to, cobalt, tungsten, ruthenium, molybdenum, copper, or combinations thereof. Other suitable conductive materials are within the contemplated scope of the present disclosure. In some embodiments, a barrier layer (not shown) may be conformally formed on the dielectric layer 26 and in the opening 28 (see FIG. 5) before the conducive material layer 29′ is formed. In some embodiment, the barrier layer may include, for example, but not limited to, tantalum, cobalt, ruthenium, tantalum nitride, or combinations thereof. Other suitable materials for the barrier layer are within the contemplated scope of the present disclosure.

The conductive interconnect 29 includes a lower interconnect portion 291 disposed on and connected to the metal contact 24 (or the conductive bulk region 242 of the metal contact 24), and an upper interconnect portion 292 disposed on the lower interconnect portion 291 opposite to the metal contact 24. A cross-sectional area of the upper interconnect portion 292 taken in the horizontal plane parallel to the substrate 10 (see FIG. 2) is greater than a cross-sectional area of the lower interconnect portion 291 taken in the horizontal plane. A cross-sectional shape of the upper interconnect portion 292 taken in the horizontal plane is an oval-like shape, while a cross-sectional shape of the lower interconnect portion 291 taken in the horizontal plane is a circle-like shape. In some embodiments, a dimension (W1) of an upper surface (an oval-like upper surface) of the upper interconnect portion 292 in the second direction (the X direction) is greater than a dimension (W2) of the lower interconnect portion 291 in the second direction by an amount ranging from about 2 nm to about 40 nm. In some embodiments, the conductive interconnect 29 has a height ranging from about 50 Å to about 500 Å.

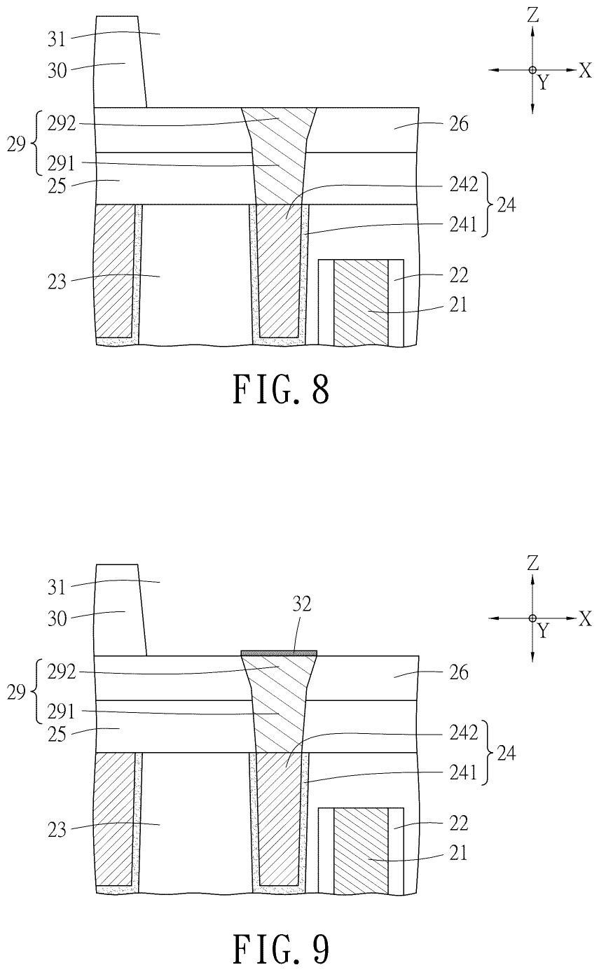

Referring to FIG. 1 and the example illustrated in FIG. 8, the method 100A proceeds to step 5A, where a patterned dielectric layer 30 is formed. In some embodiments, the patterned dielectric layer 30 may be formed by depositing a dielectric material layer on the dielectric layer 26 by a suitable deposition process (for example, but not limited to, ALD, CVD, PEALD, PECVD, or PVD), and patterning the dielectric material layer using a suitable etching process (for example, but not limited to, a dry etching process or a wet etching process) through an opening pattern formed in a patterned mask layer (not shown) disposed on the dielectric material layer. The material for forming the patterned dielectric layer 30 (or the dielectric material layer) may be the same as or similar to that for forming the dielectric layer 23 described above with reference to FIG. 2, and details thereof are omitted for the sake of brevity. A plurality of trenches 31 are thus formed in the patterned dielectric layer 30, extend in the second direction (the X direction), and are spaced apart from one another in the third direction (the Y direction). The upper interconnect portion 292 of the conductive interconnect 29 is exposed from a corresponding one of the trenches 31. Only one of the trenches 31 is shown in FIG. 8.

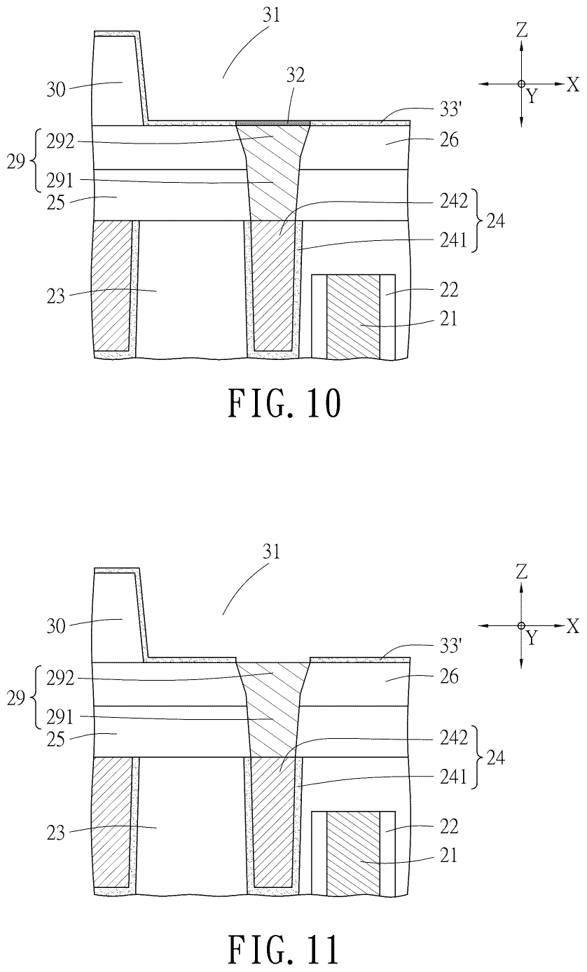

Referring to FIG. 1 and the example illustrated in FIG. 9, the method 100A proceeds to step 6A, where a blocking layer 32 is formed on the upper interconnect portion 292 of the conductive interconnect 29. The blocking layer 32 is selectively formed to cover an oval-like shaped top surface of the upper interconnect portion 292 of the conductive interconnect 29 without being formed on the dielectric layer 26 and the patterned dielectric layer 30. In some embodiments, the blocking layer 32 has a thickness ranging from about 1 nm to about 5 nm. If the thickness of the blocking layer 32 is less than 1 nm, the upper interconnect portion 292 of the conductive interconnect 29 may not be blocked sufficiently in a subsequent step of forming a barrier material layer 33′, which will be described below with reference to FIG. 10. If the thickness of the blocking layer 32 is greater than 5 nm, the blocking layer 32 may not be fully removed in a subsequent step of removing the blocking layer 32, which will be described below with reference to FIG. 11.

In some embodiment, the blocking layer 32 may be formed by a suitable deposition process (for example, but not limited to, ALD, molecular layer deposition (MLD), CVD, spin-on deposition, dipping deposition, or spay deposition). Other suitable deposition processes are within the contemplated scope of the present disclosure. In some embodiments, the deposition process for forming the blocking layer 32 is conducted at a temperature ranging from a room temperature to about 450° C. In some embodiments, an acidic solution including a blocking material is used for forming the blocking layer 32, so as to prevent the conductive interconnect 29 from being damaged (e.g., being corroded) if an alkaline solution including the blocking material is used for forming the blocking layer 32. In some embodiments, the blocking material includes, for example, but not limited to, a polymer inhibitor that contains carbon, oxygen, nitrogen, chlorine, fluorine, or combinations thereof; a self-assembly monolayer (SAM) precursor (e.g., phosphonic acid, thiol, a silane-based compound, or the like, or combinations thereof); a non-SAM precursor (e.g., benzotriazole or the like); or combinations thereof. In some embodiments, the acidic solution has a pH value of, for example, but not limited to, at least about 6.0 and less than about 7.0, so as to prevent the upper interconnect portion 292 of the conductive interconnect 29 from being damaged (e.g., being corroded) by the acidic solution. The acidic solution further includes an acid compound, an organic solvent, and water. In some embodiments, the acid compound may be an organic acid compound (for example, but not limited to, citric acid, formic acid, acetic acid, propanoic acid, butyric acid, pentanoic acid, or the like, or combinations thereof), an inorganic acid compound (for example, but not limited to, hydrochloric acid, sulfuric acid, phosphoric acid, or the like, or combinations thereof), or a combination of the organic acid compound and the inorganic acid compound. In some embodiments, the organic solvent includes, for example, but not limited to, alcohol (e.g., methanol, ethanol, isopropyl alcohol, or the like, or combinations thereof). A ratio of the organic solvent to water should be maintained at a suitable range so as to prevent metal (for example, but not limited to, tungsten) included in the conductive interconnect 29 from being dissolved in the acidic solution. In some embodiments, a pH adjusting agent may be added to the acidic solution when the acidic solution is used to form the blocking layer 32. In some embodiments, the pH adjusting agent includes, for example, but not limited to, the acid compound described above, or a buffer which includes the acid compound and a salt compound, so as to maintain the acidic solution in a suitable pH value (for example, but not limited to, a pH value of at least about 6.0 and less than about 7.0). In some embodiments, the salt compound includes, for example, but not limited to, a citrate compound (e.g., sodium citrate or the like), an acetate compound (e.g., sodium acetate or the like), or a combination thereof. The blocking layer 32 may be configured as a single layer structure or a multi-layered structure, and is bonded to the upper interconnect portion 292 of the conductive interconnect 29 by means of chemical adsorption (for example, but not limited to, covalent bonding, coordinate bonding, or the like), physical adsorption (for example, but not limited to, hydrogen bonding, van der Waals bonding, static electricity bonding, or the like), or a combination thereof.

Referring to FIG. 1 and the example illustrated in FIG. 10, the method 100A proceeds to step 7A, where the barrier material layer 33′ is formed. The barrier material layer 33′ is selectively formed on the patterned dielectric layer 30 and portions of the dielectric layer 26 exposed from the trenches 31 without being formed on the upper interconnect portion 292 of the conductive interconnect 29. In some embodiments, the barrier material layer 33′ includes, for example, but not limited to, tantalum, ruthenium, cobalt, tantalum nitride, or the like, or combinations thereof. Other suitable materials for the barrier material layer 33′ are within the contemplated scope of the present disclosure. In some embodiments, the barrier material layer 33′ may be formed by a suitable deposition process, for example, but not limited to, ALD, CVD, or PVD. Other suitable deposition processes are within the contemplated scope of the present disclosure.

Referring to FIG. 1 and the example illustrated in FIG. 11, the method 100A proceeds to step 8A, where the blocking layer 32 of the structure shown in FIG. 10 is removed. In some embodiments, the blocking layer 32 may be removed by, for example, but not limited to, a thermal annealing treatment, a plasma treatment, or a wet cleaning treatment. Other suitable treatments are within the contemplated scope of the present disclosure. In some embodiments, a precursor gas for generating plasma in the plasma treatment includes, for example, but not limited to, hydrogen gas, nitrogen gas, ammonia gas, oxygen gas, fluorocarbon gas (CₓF_{y}, wherein each of x and y is equal to or greater than 1), or combinations thereof. Other suitable precursor gases are within the contemplated scope of the present disclosure. In some embodiments, the wet cleaning treatment is conducted by an acid etching process. Other suitable cleaning treatments are within the contemplated scope of the present disclosure. After the blocking layer 32 is removed, the oval-like shaped top surface of the upper interconnect portion 292 of the conductive interconnect 29 is exposed from the barrier material layer 33′.

Referring to FIG. 1 and the examples illustrated in FIGS. 12 and 13, the method 100A proceeds to step 9A, where a plurality of conductive interconnects (M0) are formed. The conductive interconnects (M0) are formed in the trenches 31 (see, for example, FIG. 11), respectively, extend in the second directions (the X direction), and are spaced apart from each other in the third direction (the Y direction). Each of the conductive interconnects (M0) serves as a metal line, and includes a barrier layer 33, a liner layer 34 disposed on the barrier layer 33, and a conductive bulk region 35 disposed on the liner layer 34 opposite to the barrier layer 33. The upper interconnect portion 292 of the conductive interconnect 29, which serves as a via contact, is connected to one of the conductive interconnects (M0), which serves as metal lines. The oval-like shaped top surface of the upper interconnect portion 292 is directly connected to the liner layer 34 of the one of the conductive interconnects (M0) without the barrier layer 33 being formed between the upper interconnect portion 292 and the liner layer 34. That is, a barrier-free interface is formed between the upper interconnect portion 292 of the conductive interconnect 29 and the one of the conductive interconnects (M0). In some embodiments, the conductive interconnects (M0) are formed by sub-steps (i) and (ii) described below.

In sub-step (i), a liner material layer for forming the liner layer 34 is conformally deposited on the barrier material layer 33′ (see FIG. 11), and a conductive material layer for forming the conductive bulk region 35 is formed on the liner material layer to fill the trenches 31 (see FIG. 11). In some embodiments, each of the liner material layer and the conductive material layer may be formed independently by a suitable deposition process, for example, but not limited to PVD, CVD, ALD, PEALD, or PECVD. Other suitable deposition techniques are within the contemplated scope of the present disclosure. Excess of the barrier material layer 33′, excess of the liner material layer, and excess of the conductive material layer over the patterned dielectric layer 30 are removed by a planarization process (for example, but not limited to, the CMP process) so as to form the conductive interconnects (M0). In some embodiments, the liner layer 34 (or the liner material layer) includes, for example, but not limited to, cobalt, ruthenium, tantalum, or combinations thereof. Other suitable materials for the liner layer 34 are within the contemplated scope of the present disclosure. In some embodiments, the conductive bulk region 35 (or the conductive metal layer) includes, for example, but not limited to, copper, tungsten, ruthenium, cobalt, molybdenum, or combinations thereof. Other suitable materials for the conductive bulk region 35 are within the contemplated scope of the present disclosure.

An interconnect structure of this disclosure includes a conductive interconnect serving as a via contact and connected to a conductive feature (for example, a conductive contact disposed on and connected to a gate structure or a source/drain region of a transistor), and an another conducive interconnect disposed on and connected to the conductive interconnect and serving as a metal line. The conductive interconnect serving as the via contact includes an upper interconnect portion with an oval-like shaped cross section and a lower interconnect portion with a circle-like shaped cross section that is smaller than the oval-like shaped cross section. In addition, a barrier-free interface is formed between the conductive interconnect and the another conductive interconnect. Therefore, a total value of interface resistance and bulk resistance of the conductive interconnect serving as the via contact is reduced significantly, for example, by a percentage ranging from about 1% to about 70%, compared to a via contact with the circle-like shaped cross section and without the barrier-free interface between the via contact and a metal line disposed on and connected to the via contact. The formation of the barrier-free interface between the conductive interconnect serving as the via contact and the another conducive interconnect serving as the metal line is achieved by selectively forming a blocking layer on the conductive interconnect serving as the via contact using an acidic solution which includes a blocking material for forming the blocking layer.

In accordance with some embodiments of the present disclosure, a method for manufacturing a semiconductor device includes: forming a first conductive interconnect which penetrates a dielectric layer disposed over a substrate in a first direction normal to the substrate; forming a patterned dielectric layer on the dielectric layer, the patterned dielectric layer being formed with a trench extending in a second direction transverse to the first direction and the first conductive interconnect being exposed from the trench; selectively forming a blocking layer to cover the first conductive interconnect, the blocking layer being formed using an acidic solution including a blocking material; selectively forming a barrier material layer on the dielectric layer and the patterned dielectric layer; removing the blocking layer so as to expose the first conductive interconnect from the barrier material layer; forming a conductive material layer on the barrier material layer; and removing a portion of the conductive material layer and a portion of the barrier material layer to form a second conductive interconnect disposed on and connected to the first conductive interconnect.

In accordance with some embodiments of the present disclosure, the acidic solution has a pH value of at least about 6.0 and less than about 7.0.

In accordance with some embodiments of the present disclosure, the blocking material includes a polymer inhibitor that contains carbon, oxygen, nitrogen, chlorine, fluorine, or combinations thereof; a self-assembly monolayer (SAM) precursor including phosphonic acid, thiol, a silane-based compound, or combinations thereof; a non-SAM precursor including benzotriazole; or combinations thereof.

In accordance with some embodiments of the present disclosure, the acidic solution further includes an acid compound, an organic solvent, and water.

In accordance with some embodiments of the present disclosure, the acid compound includes citric acid, formic acid, acetic acid, propanoic acid, butyric acid, pentanoic acid, hydrochloric acid, sulfuric acid, phosphoric acid, or combinations thereof.

In accordance with some embodiments of the present disclosure, the organic solvent includes methanol, ethanol, isopropyl alcohol, or combinations thereof.

In accordance with some embodiments of the present disclosure, a pH adjusting agent is added into the acidic solution when the acidic solution is used to form the blocking layer. The pH adjusting agent includes the acid, or a buffer including the acid and a salt compound.

In accordance with some embodiments of the present disclosure, the salt compound includes a citrate compound, an acetate compound, or a combination thereof.

In accordance with some embodiments of the present disclosure, the method for manufacturing a semiconductor device further includes, after removal of the blocking layer and before formation of the conductive material layer, forming a liner material layer on the barrier material layer, so that the second conductive interconnect is formed. The second conductive interconnect includes a barrier layer formed from the barrier material layer; a liner layer formed from the liner material layer, and configured to be disposed on the barrier layer, to protrude through the barrier layer, and to be connected to the first conductive interconnect; and a conductive bulk region formed from the conductive material layer and disposed on the liner layer opposite to the barrier layer.

In accordance with some embodiments of the present disclosure, a method for manufacturing a semiconductor device includes: forming a metal contact connected to a semiconductor feature disposed on a substrate; forming an etch stop layer on the metal contact; forming a dielectric layer on the etch stop layer opposite to the metal contact; forming an opening to penetrate the dielectric layer and the etch stop layer so as to expose the metal contact, the opening including an upper opening portion and a lower opening portion disposed below and in spatial communication with the upper opening portion, the lower opening portion having a cross-sectional shape and the upper opening portion having a cross-sectional shape that is the same as the cross-sectional shape of the lower opening portion, the cross-sectional shape of each of the upper opening portion and the lower opening portion being taken in a horizontal plane parallel to the substrate; widening the upper opening portion by a directional etching process, so that the upper opening portion is reshaped to permit the cross-sectional shape of the upper opening portion to be different from the cross-sectional shape of the lower opening portion; and filling a conductive material layer in the upper opening portion and the lower opening portion after the upper opening portion is reshaped, so as to form a first conductive interconnect connected to the metal contact.

In accordance with some embodiments of the present disclosure, the directional etching process includes: conducting a first directional etching at a first tilt orientation, which is parallel to a first vertical plane perpendicular to the horizontal plane and which forms a first tilt angle relative to a second plane perpendicular to the horizontal plane and the first vertical plane; and conducting a second directional etching at a second tilt orientation, which is parallel to the first vertical plane and which forms a second tilt angle relative to the second vertical plane. The second tilt orientation is counter to the first tilt orientation relative to the second vertical plane.

In accordance with some embodiments of the present disclosure, each of the first tilt angle and the second tilt angle is greater than about 0° and up to about 70°.

In accordance with some embodiments of the present disclosure, the first tilt angle is equal to the second tilt angle.

In accordance with some embodiments of the present disclosure, the conductive material layer includes cobalt, tungsten, ruthenium, molybdenum, copper, or combinations thereof.

In accordance with some embodiments of the present disclosure, the method for manufacturing a semiconductor device further includes forming a second conductive interconnect connected to the first conductive interconnect, The second conductive interconnect includes a barrier layer formed on the dielectric layer without being formed on the first conductive interconnect; a liner layer formed on the barrier layer, protruding through the barrier layer, and connected to the first conductive interconnect; and a conductive bulk region formed on the liner layer opposite to the barrier layer.

In accordance with some embodiments of the present disclosure, after the directional etching process, the cross-sectional shape of the upper opening portion is an oval shape, and the cross-sectional shape of the lower opening portion is a circle shape.

In accordance with some embodiments of the present disclosure, a semiconductor device includes a substrate, a semiconductor feature disposed on the substrate, a metal contact connected to the semiconductor feature, a first conductive interconnect, and a second conductive interconnect connected to the first conductive interconnect. The first conductive interconnect includes a lower interconnect portion disposed on and connected to the metal contact, and an upper interconnect portion disposed on the lower interconnect portion opposite to the metal contact. A cross-sectional area of the upper interconnect portion is greater than a cross-sectional area of the lower interconnect portion. The cross-sectional area of each of the upper interconnect portion and the lower interconnect portion is taken in a horizontal plane parallel to the substrate. The second conductive interconnect includes a barrier layer; a liner layer formed on the barrier layer, protruding through the barrier layer, and connected to the first conductive interconnect; and a conductive bulk region formed on the liner layer opposite to the barrier layer.

In accordance with some embodiments of the present disclosure, the first conductive interconnect includes cobalt, tungsten, ruthenium, molybdenum, copper, or combinations thereof.

In accordance with some embodiments of the present disclosure, a cross-sectional shape of the upper interconnect portion is oval, and a cross-sectional shape of the lower interconnect portion is circle. The cross-sectional shape of each of the upper interconnect portion and the lower interconnect portion is taken in the horizontal plane.

In accordance with some embodiments of the present disclosure, the semiconductor feature includes a transistor.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a first conductive interconnect which penetrates a dielectric layer disposed over a substrate in a first direction normal to the substrate;
forming a patterned dielectric layer on the dielectric layer, the patterned dielectric layer being formed with a trench extending in a second direction transverse to the first direction and the first conductive interconnect being exposed from the trench;
selectively forming a blocking layer to cover the first conductive interconnect, the blocking layer being formed using an acidic solution including a blocking material;
selectively forming a barrier material layer on the dielectric layer and the patterned dielectric layer;
removing the blocking layer so as to expose the first conductive interconnect from the barrier material layer;
forming a conductive material layer on the barrier material layer; and
removing a portion of the conductive material layer and a portion of the barrier material layer to form a second conductive interconnect disposed on and connected to the first conductive interconnect.

2. The method as claimed in claim 1, wherein the acidic solution has a pH value of at least 6.0 and less than 7.0.

3. The method as claimed in claim 1, wherein the blocking material includes:
a polymer inhibitor that contains carbon, oxygen, nitrogen, chlorine, fluorine, or combinations thereof;
a self-assembly monolayer (SAM) precursor including phosphonic acid, thiol, a silane-based compound, or combinations thereof;
a non-SAM precursor including benzotriazole; or
combinations thereof.

4. The method as claimed in claim 1, wherein the acidic solution further includes an acid compound, an organic solvent, and water.

5. The method as claimed in claim 4, wherein the acid compound includes citric acid, formic acid, acetic acid, propanoic acid, butyric acid, pentanoic acid, hydrochloric acid, sulfuric acid, phosphoric acid, or combinations thereof.

6. The method as claimed in claim 4, wherein the organic solvent includes methanol, ethanol, isopropyl alcohol, or combinations thereof.

7. The method as claimed in claim 4, wherein a pH adjusting agent is added into the acidic solution when the acidic solution is used to form the blocking layer, the pH adjusting agent including the acid, or a buffer including the acid and a salt compound.

8. The method as claimed in claim 7, wherein the salt compound includes a citrate compound, an acetate compound, or a combination thereof.

9. The method as claimed in claim 1, further comprising, after removal of the blocking layer and before formation of the conductive material layer, forming a liner material layer on the barrier material layer, so that the second conductive interconnect is formed and includes:
a barrier layer formed from the barrier material layer,
a liner layer formed from the liner material layer, and configured to be disposed on the barrier layer, to protrude through the barrier layer, and to be connected to the first conductive interconnect, and
a conductive bulk region formed from the conductive material layer and disposed on the liner layer opposite to the barrier layer.

10. A method for manufacturing a semiconductor device, comprising:
forming a metal contact connected to a semiconductor feature disposed on a substrate;
forming an etch stop layer on the metal contact;
forming a dielectric layer on the etch stop layer opposite to the metal contact;
forming an opening to penetrate the dielectric layer and the etch stop layer so as to expose the metal contact, the opening including an upper opening portion and a lower opening portion disposed below and in spatial communication with the upper opening portion, the lower opening portion having a cross-sectional shape and the upper opening portion having a cross-sectional shape that is the same as the cross-sectional shape of the lower opening portion, the cross-sectional shape of each of the upper opening portion and the lower opening portion being taken in a horizontal plane parallel to the substrate;
widening the upper opening portion by a directional etching process, so that the upper opening portion is reshaped to permit the cross-sectional shape of the upper opening portion to be different from the cross-sectional shape of the lower opening portion; and
filling a conductive material layer in the upper opening portion and the lower opening portion after the upper opening portion is reshaped, so as to form a first conductive interconnect connected to the metal contact.

11. The method as claimed in claim 10, wherein the directional etching process includes:
conducting a first directional etching at a first tilt orientation, which is parallel to a first vertical plane perpendicular to the horizontal plane and which forms a first tilt angle relative to a second plane perpendicular to the horizontal plane and the first vertical plane; and
conducting a second directional etching at a second tilt orientation, which is parallel to the first vertical plane and which forms a second tilt angle relative to the second vertical plane, the second tilt orientation being counter to the first tilt orientation relative to the second vertical plane.

12. The method as claimed in claim 11, wherein each of the first tilt angle and the second tilt angle is greater than 0° and up to 70°.

13. The method as claimed in claim 11, wherein the first tilt angle is equal to the second tilt angle.

14. The method as claimed in claim 11, wherein the conductive material layer includes cobalt, tungsten, ruthenium, molybdenum, copper, or combinations thereof.

15. The method as claimed in claim 11, further comprising forming a second conductive interconnect connected to the first conductive interconnect and including:
a barrier layer formed on the dielectric layer without being formed on the first conductive interconnect,
a liner layer formed on the barrier layer, protruding through the barrier layer, and connected to the first conductive interconnect, and
a conductive bulk region formed on the liner layer opposite to the barrier layer.

16. The method as claimed in claim 10, wherein after the directional etching process, the cross-sectional shape of the upper opening portion is an oval shape, and the cross-sectional shape of the lower opening portion is a circle shape.

17. A semiconductor device, comprising:
a substrate;
a semiconductor feature disposed on the substrate;
a metal contact connected to the semiconductor feature;
a first conductive interconnect including
a lower interconnect portion disposed on and connected to the metal contact, and
an upper interconnect portion disposed on the lower interconnect portion opposite to the metal contact, a cross-sectional area of the upper interconnect portion being greater than a cross-sectional area of the lower interconnect portion, the cross-sectional area of each of the upper interconnect portion and the lower interconnect portion being taken in a horizontal plane parallel to the substrate; and
a second conductive interconnect connected to the first conductive interconnect, and including
a barrier layer,
a liner layer formed on the barrier layer, protruding through the barrier layer, and connected to the first conductive interconnect, and
a conductive bulk region formed on the liner layer opposite to the barrier layer.

18. The semiconductor device as claimed in claim 17, wherein the first conductive interconnect includes cobalt, tungsten, ruthenium, molybdenum, copper, or combinations thereof.

19. The semiconductor device as claimed in claim 17, wherein a cross-sectional shape of the upper interconnect portion is oval, and a cross-sectional shape of the lower interconnect portion is circle, the cross-sectional shape of each of the upper interconnect portion and the lower interconnect portion being taken in the horizontal plane.

20. The semiconductor device as claimed in claim 17, wherein the semiconductor feature includes a transistor.
